(19) United States
(12) Patent Application Publication
(10) Pub. No.: US 2024/0421173 A1
(43) Pub. Date: Dec. 19, 2024

(54) DISPLAY PANEL AND DISPLAY PANEL MANUFACTURING METHOD

(71) Applicant: WUHAN CHINA STAR OPTOELECTRONICS TECHNOLOGY CO., LTD., Wuhan, Hubei (CN)

(72) Inventors: Jiyue SONG, Wuhan, Hubei (CN); Fei AI, Wuhan, Hubei (CN); Dewei SONG, Wuhan, Hubei (CN); Fan GONG, Wuhan, Hunei (CN)

(21) Appl. No.: 17/596,881

(22) PCT Filed: Dec. 15, 2021
(86) PCT No.: PCT/CN2021/138354

§ 371 Date: Aug. 27, 2024

(30) Foreign Application Priority Data
Dec. 8, 2021 (CN) 202111489394.8

(51) Int. Cl. H01L 27/146; G02F 1/1333; G02F 1/1368

(52) U.S. Cl. CPC H01L 27/14636; G02F 1/133357; G02F 1/1368; H01L 27/14645; H01L 27/14683; H01L 27/14612

(57) ABSTRACT

An embodiment of the present application discloses a display panel and a display panel manufacturing method. The photosensitive element and the thin film transistor device are disposed on the same side of the substrate. Some components of the photosensitive element and some components of the thin film transistor device can be manufactured by the same step, and therefore can improve integration of the photosensitive element on the array substrate. Furthermore, the photosensitive element can be integrated in the display panel with reduced photomasks and a lowered cost.

### FIELD OF INVENTION

The present application relates to a field of display technologies, especially to a display panel and a display panel manufacturing method.

### BACKGROUND OF INVENTION

With the rapid development of the display panel industry, in addition to the high resolution, wide viewing angle, and low power consumption of the display, people also put forward other requirements for the display panel. An ambient light detection function can automatically adjust the screen brightness according to the brightness of the external environment, or according to the external environment, automatically turn on the flash or fill the light when taking images. During research and practice of conventional technologies, inventors of the present application have found that the current environmental light photosensitive element basically adopts a plug-in method, which inevitably increases the production cost.

### SUMMARY OF INVENTION

### Technical Issue

The embodiment of the present application provides an array substrate and a liquid crystal display panel that can buffer conflicts of pre-tilt angles of liquid crystal molecules corresponding to a boundary between adjacent alignment regions in a pixel to further mitigate dark areas of a curved display screen.

### Solution for the Issue

### Technical Solution

The embodiment of the present application provides a display panel and a display panel manufacturing method that can employ less photomasks to integrate photosensitive elements into the display panel.

An embodiment of the present application provides a display panel comprising:
a substrate;
a thin film transistor device, wherein the thin film transistor device is disposed on the substrate, the thin film transistor device comprises an active layer, an interlayer insulation layer, and a source electrode wiring, the active layer comprises a semiconductor portion and a source electrode portion and a drain electrode portion on two sides of the semiconductor portion, the interlayer insulation layer is disposed on the active layer, and the source electrode wiring is disposed on the interlayer insulation layer; and
a photosensitive element, wherein the photosensitive element and the thin film transistor device are disposed on a same side of the substrate;
wherein a first through hole and a second through hole are defined in the interlayer insulation layer, the source electrode wiring is connected to the source electrode portion through the first through hole, and at least a portion of the photosensitive element is disposed in the second through hole.

Optionally, in some embodiments of the present application, the photosensitive element at least comprises a first electrode and a photosensitive layer sequentially stacked on each other; wherein the first electrode is electrically connected to the drain electrode portion, and at least a portion of the photosensitive layer is filled in the second through hole.

Optionally, in some embodiments of the present application, a material of the first electrode is one of doped polysilicon, doped amorphous silicon, metal, or a combination thereof, and a material of the photosensitive layer is intrinsic amorphous silicon.

Optionally, in some embodiments of the present application, a material of the first electrode and the drain electrode portion are is N-type doped polysilicon, and the first electrode and the drain electrode portion are disposed in a same layer.

Optionally, in some embodiments of the present application, the second through hole extends from a surface of a side of the interlayer insulation layer away from the substrate to a surface of a side of the first electrode away from the substrate.

Optionally, in some embodiments of the present application, the display panel further comprises gate electrode insulation layer, the thin film transistor device further comprises gate electrode, the gate electrode insulation layer is disposed on the active layer, the gate electrode is disposed on the gate electrode insulation layer, the interlayer insulation layer is disposed on the gate electrode and extends to the gate electrode insulation layer, and the first through hole and the second through hole extend to a surface of a side of the gate electrode insulation layer near the substrate.

Optionally, in some embodiments of the present application, a recess is defined in the source electrode portion, the source electrode wiring extends to the recess and contacts the recess.

Optionally, in some embodiments of the present application, the thin film transistor device further comprises gate electrode and drain electrode wiring, the first electrode comprises a first sub-electrode and a second sub-electrode, the gate electrode is disposed on the substrate, and the gate electrode and the active layer are disposed insulatively in different layers, the drain electrode wiring is connected to the drain electrode portion, the drain electrode wiring and the source electrode wiring are disposed in a same layer, the first sub-electrode and the gate electrode are disposed in a same layer, and the first sub-electrode is connected to the drain electrode portion through the drain electrode wiring, and the second sub-electrode is disposed on a surface of a side of the first sub-electrode away from the substrate.

Optionally, in some embodiments of the present application, the display panel further comprises gate electrode insulation layer, the interlayer insulation layer further comprises third through hole, the gate electrode insulation layer is disposed on the active layer, the gate electrode is disposed on the gate electrode insulation layer, the interlayer insulation layer is disposed on the gate electrode and extends to the gate electrode insulation layer, the source electrode wiring and the drain electrode wiring are connected to the source electrode portion and the drain electrode portion respectively through the first through hole, the second sub-electrode is connected to the first sub-electrode through the second through hole, the drain electrode wiring is further connected to the first sub-electrode through the third through hole.

Optionally, in some embodiments of the present application, the second through hole extends from a surface of a side of the interlayer insulation layer away from the substrate to a surface of a side of the first sub-electrode away from the substrate.

Optionally, in some embodiments of the present application, the display panel further comprises a protection layer, the protection layer is disposed on a surface of a side of the photosensitive layer away from the substrate.

Optionally, in some embodiments of the present application, the display panel further comprises top electrode layer, the top electrode layer is disposed on the protection layer, the photosensitive element further comprises a second electrode, the second electrode and the top electrode layer are disposed in a same layer, a first via hole is defined in the protection layer, the second electrode is connected to the photosensitive layer through the first via hole.

Optionally, in some embodiments of the present application, the display panel further comprises a planarization layer, the planarization layer is disposed on the protection layer; wherein a second via hole is defined in the planarization layer, a diameter of the first via hole is less than a diameter of the second via hole, the top electrode layer and the second electrode are disposed on the planarization layer, and the second electrode is connected to the photosensitive layer through the first via hole and the second via hole.

Optionally, in some embodiments of the present application, a side of the photosensitive layer away from the substrate protrudes from a surface of a side of the interlayer insulation layer away from the substrate, and a width of a side of the photosensitive layer away from the substrate is greater than a width of a side of the second through hole away from the substrate.

Optionally, in some embodiments of the present application, the display panel further comprises a light shielding layer, a buffer layer, a gate electrode insulation layer, a first metal layer, a second metal layer, a planarization layer, a bottom electrode layer, a passivation layer, and a top electrode layer sequentially stacked on one another.

Optionally, in some embodiments of the present application, the photosensitive element comprises a first electrode, a photosensitive layer, and a second electrode sequentially stacked on one another; the first electrode is formed by the drain electrode portion that is reused, the photosensitive layer is disposed on the drain electrode portion, the second electrode is formed by the top electrode layer in the display panel that is reused.

Accordingly, the embodiment of the present application provides a display panel manufacturing method comprising:
providing a substrate;
forming a thin film transistor device and a photosensitive element on the substrate;
wherein the step of forming a thin film transistor device and a photosensitive element on the substrate comprises:
forming an active layer on the substrate;
doping two ends of the active layer to form a semiconductor portion and a source electrode portion and a drain electrode portion on two sides of the semiconductor portion;
forming an interlayer insulation layer on the substrate;
forming a first through hole and a second through hole in the interlayer insulation layer by a same photomask;
forming a source electrode wiring on the substrate, wherein the source electrode wiring is connected to the source electrode portion through the first through hole;
forming at least a portion of the photosensitive element in the second through hole.

Optionally, in some embodiments of the present application, the step of forming a photosensitive element on the substrate, comprises steps as follows:
forming a first electrode on the substrate, wherein the first electrode is electrically connected to the drain electrode portion; and
forming a photosensitive layer on the interlayer insulation layer, wherein the photosensitive layer is connected to the first electrode through the second through hole.

Optionally, in some embodiments of the present application, the step of forming a photosensitive layer on the interlayer insulation layer, comprises steps as follows:
depositing a photosensitive material on the substrate; and
patterning the photosensitive material to from a photosensitive layer, and simultaneously making the first through hole extend to a surface of a side of the active layer near the substrate.

Optionally, in some embodiments of the present application, the first electrode comprises a first sub-electrode and a second sub-electrode, after the step of forming an active layer on the substrate, the method further comprises steps as follows:
forming a gate electrode insulation layer on the active layer; and
forming a gate electrode and the first sub-electrode on the gate electrode insulation layer;
forming an interlayer insulation layer on the gate electrode;
forming a third through hole in the interlayer insulation layer by the same photomask forming the first through hole and the second through hole; and
further forming a drain electrode wiring and the second sub-electrode on the interlayer insulation layer, wherein the source electrode wiring and the drain electrode wiring are connected to the source electrode portion and the drain electrode portion respectively through the first through hole, the second sub-electrode is connected to the first sub-electrode through the second through hole, and the drain electrode wiring is connected to the first sub-electrode through the third through hole.

### Advantages of Invention

### Advantages

The embodiment of the present application employs a photosensitive display panel with a new integrated structure. The display panel provided by the embodiment of the present application integrates a photosensitive element on an array substrate. The photosensitive element and the thin film transistor device are disposed on the same side of the substrate. Some components of the photosensitive element and some components of the thin film transistor device can be manufactured by the same step, and therefore can improve integration of the photosensitive element on the array substrate. Furthermore, after improvement of integration, influence to a thickness of the display panel can be reduced to make the display panel after integrated lighter and more compact. Furthermore, because no additional process step is increased, a manufacturing cost can be effectively controlled. As such, the photosensitive element can be integrated in the display panel with reduced photomasks and a lowered cost.

### BRIEF DESCRIPTION OF DRAWINGS

### Description of Drawings

To more clearly elaborate on the technical solutions of embodiments of the present invention or prior art, appended figures necessary for describing the embodiments of the present invention or prior art will be briefly introduced as follows. Apparently, the following appended figures are merely some embodiments of the present invention. A person of ordinary skill in the art may acquire other figures according to the appended figures without any creative effort.

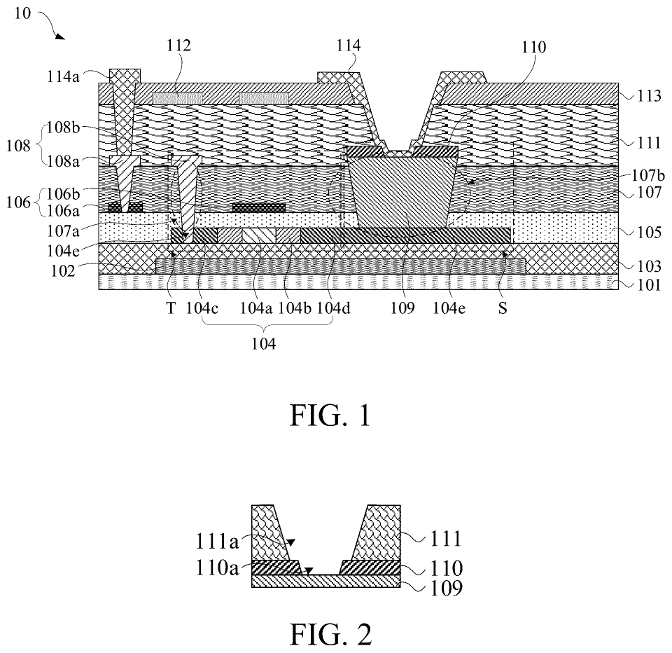

FIG. 1 is a first schematic structural view of a display panel provided by an embodiment of the present application;

FIG. 2 is a partial schematic structural view of an array substrate provided by the embodiment of the present application;

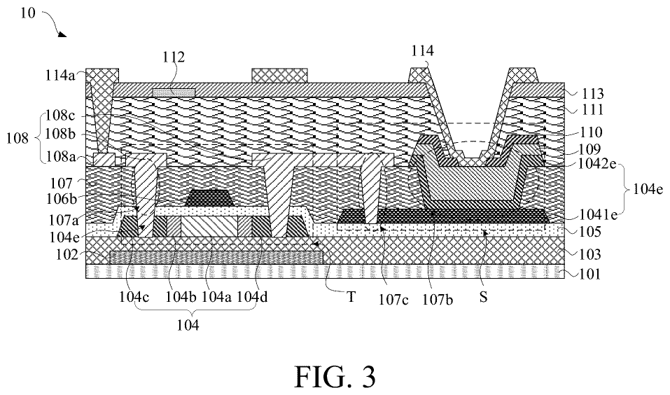

FIG. 3 is a second schematic structural view of the display panel provided by the embodiment of the present application;

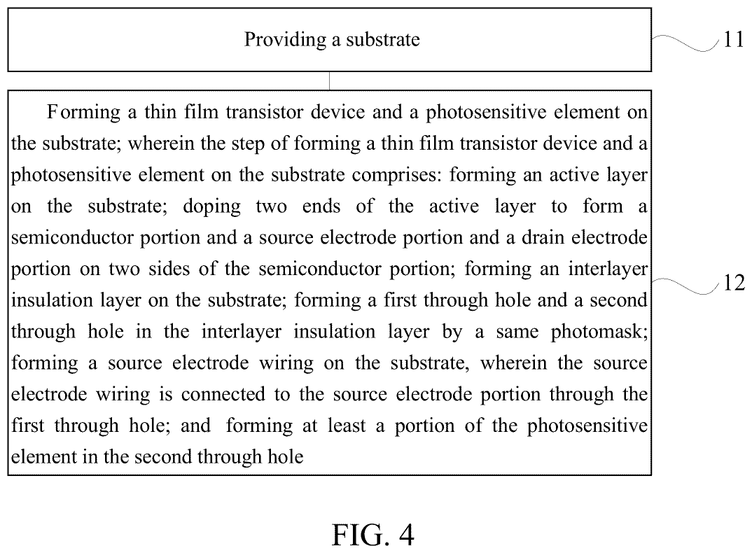

FIG. 4 is a flowchart of a display panel manufacturing method provided by the embodiment of the present application; and

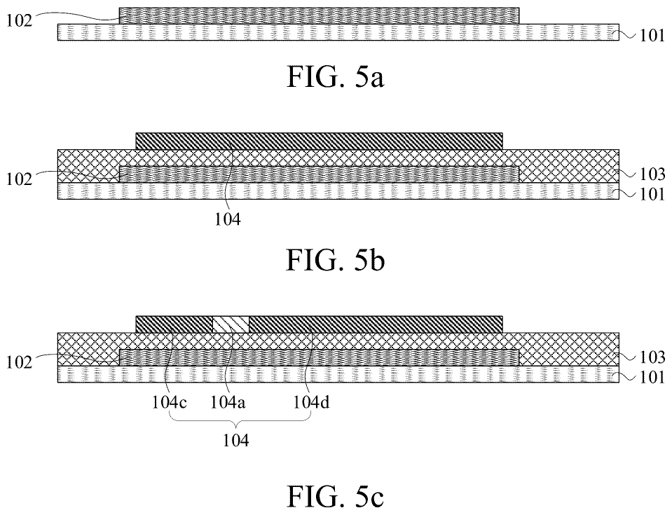

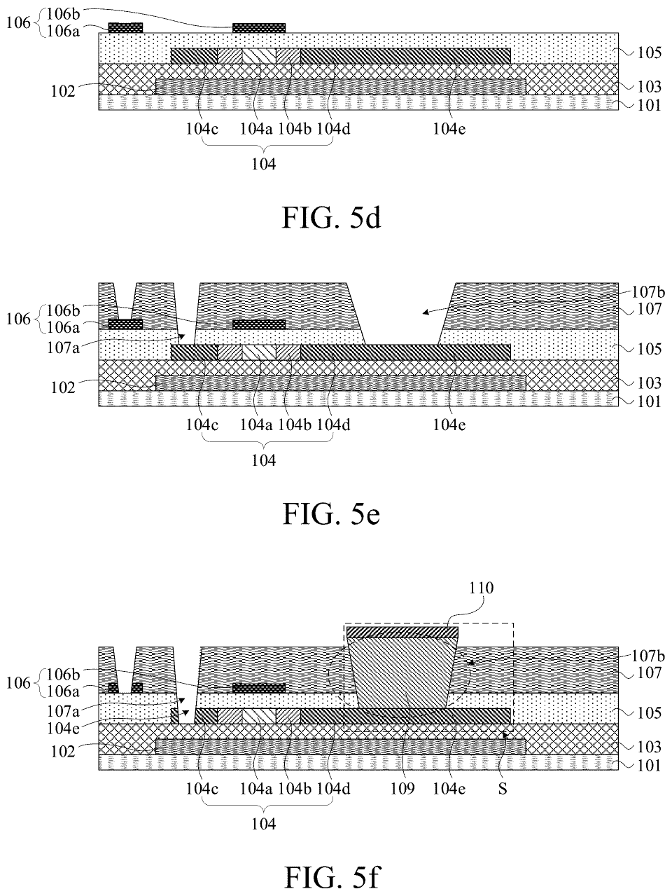

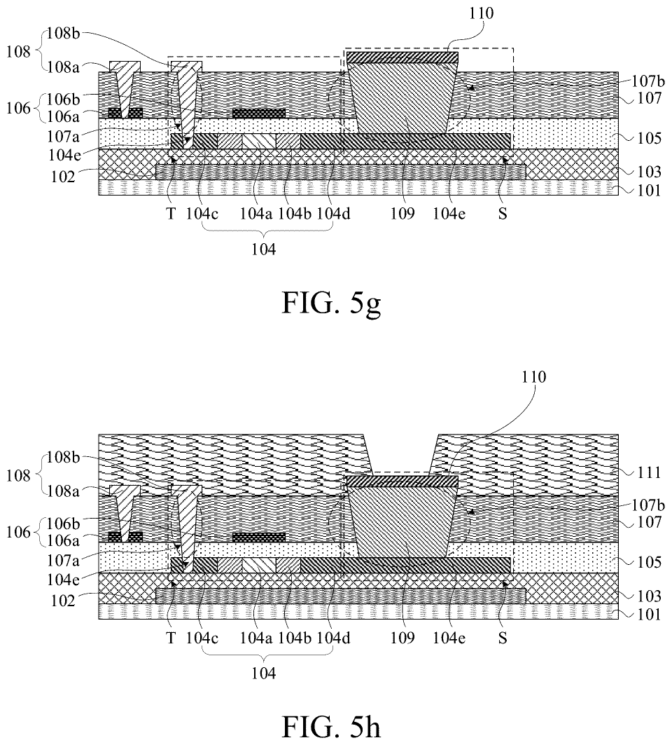

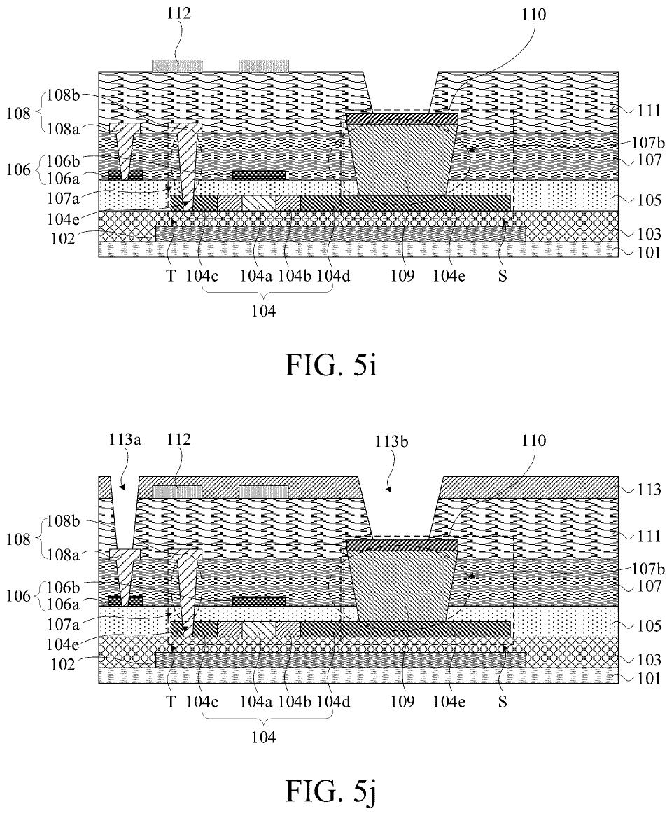

FIGS. 5a to 5j are schematic views of steps of the display panel manufacturing method provided by the embodiment of the present application.

### DETAILED DESCRIPTION OF EMBODIMENTS OF INVENTION

### Detailed Description of Invention

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when are not specified to the contrary explanation, usually refer to the upper and lower states of the device in actual use or working conditions, specifically according to the direction of the figures in the drawings. Furthermore, “inner” and “outer” refer to the outline of the device.

The embodiment of the present application provides a display panel and a display panel manufacturing method, which will be described as follows. It should be explained that a describing order of the following embodiments does not serve as an order of priority for the embodiments.

With reference to FIG. 1, FIG. 1 is a first schematic structural view of a display panel provided by an embodiment of the present application. The display panel 10 provided by the embodiment of the present application comprises a substrate 101, a thin film transistor device T, and a photosensitive element S. The thin film transistor device T is disposed on the substrate 101. The thin film transistor device T comprises an active layer 104, an interlayer insulation layer 107, and a source electrode wiring 108b. The active layer 104 comprises a semiconductor portion 104a, and a source electrode portion 104c and a drain electrode portion 104d located on two sides of the semiconductor portion 104a. The interlayer insulation layer 107 is disposed on the active layer 104. The source electrode wiring 108b is disposed on the interlayer insulation layer 107. The photosensitive element S and the thin film transistor device T are disposed on a same side of the substrate 101. A first through hole 107a and a second through hole 107b are disposed on the interlayer insulation layer 107. The source electrode wiring 108b is connected to the source electrode portion 104c through the first through hole 107a. At least a portion of the photosensitive element S is disposed in the second through hole 107b.

The embodiment of the present application provides a photosensitive the display panel 10 with a new integrated structure. The display panel 10 provided by the embodiment of the present application integrates the photosensitive element S and the thin film transistor device T on the array substrate. The photosensitive element S and the thin film transistor device T are disposed on a same side of the substrate 101. The first through hole 107a and the second through hole 107b are disposed on the interlayer insulation layer 107 in the thin film transistor device T. At least a portion of the photosensitive element S is disposed in the second through hole 107b. Some components of the photosensitive element S and some components of the thin film transistor device T can be manufactured by a same step, and therefore integration of the photosensitive element S on the array substrate can be improved. Furthermore, after improvement of integration, influence to a thickness of the display panel 10 can be reduced to make the display panel 10 after integrated lighter and more compact. Furthermore, because no additional process step is increased, a manufacturing cost can be effectively controlled. The first through hole 107a and the second through hole 107b on the interlayer insulation layer 107 can be manufactured by the same photomask. As such, the photosensitive element S can be integrated in the display panel 10 with a lowered cost.

The photosensitive element S at least comprises a first electrode 104e and a photosensitive layer 109 sequentially stacked on each other. In some embodiments, the photosensitive element S can further comprise a second electrode 114. The first electrode 104e is connected to the drain electrode portion 104d.

It should be explained that the structure of the photosensitive element S can be a heterogeneous junction formed by doped polysilicon and amorphous silicon material, and can also be PIN junction in which amorphous silicon material serves as an intrinsic semiconductor layer. The present application has no specific limit to an internal film layer structure of the photosensitive element S, namely, in the embodiment of the present application, a top electrode layer 114a can be reused as the second electrode 114, or alternatively a doped semiconductor layer can be formed under the second electrode 114 to form a PIN junction.

A first through hole 107a and a second through hole 107b are disposed on the interlayer insulation layer 107. The source electrode wiring 108b is connected to the source electrode portion 104c through the first through hole 107a. The photosensitive layer 109 is connected to the first electrode 104e through the second through hole 107b. During processes, the first through hole 107a and the second through hole 107b can be formed by the same photomask to save photomasks and reduce production costs. Furthermore, a contact hole of a first metal wiring 106a and a second metal wiring 108a can also be formed by the same photomask forming the first through hole 107a and the second through hole 107b. Optionally, the second through hole 107b extends from a surface of a side of the interlayer insulation layer 107 away from the substrate 101 to a surface of a side of the first electrode 104e away from the substrate 101.

The substrate 101 is glass, function glass (sensor glass), or a flexible underlay. The function glass is obtained by sputtering a transparent metal oxide thin film conductive layer on an ultra-thin glass and annealing the glass. A material of the transparent metal oxide can be one of indium gallium zinc oxide (IGZO), indium zinc tin oxide (IZTO), indium gallium zinc tin oxide (IGZTO), indium tin oxide (ITO), indium zinc oxide (IZO), indium aluminum zinc oxide (IAZO), indium gallium tin oxide (IGTO), or antimony tin oxide (ATO). A material used by the flexible underlay is polymer material. In particular, a material used by the flexible underlay can be polyimide (Polyimide, PI), polyethylene (PE), polypropylene (PP), polystyrene (PS), polyethylene glycol terephthalate (PET), or polyethylene naphthalate two formic acid glycol ester (PEN). The polymer material has excellent flexibility, light weight, impact resistance, and are suitable for the flexible display panel. The polyimide can also achieve excellent heat resistance and stability.

Optionally, in some embodiments of the present application, a material used by the first electrode 104e is one of doped polysilicon, doped amorphous silicon, metal, or a combination thereof. A material used by the photosensitive layer 109 is intrinsic amorphous silicon.

Specifically, a material used by the first electrode 104e is polysilicon (Poly-Si), a material used by the photosensitive layer 109 is amorphous silicon (α-Si). Poly-Si has excellent process compatibility, and is inactive in a normal temperature. Therefore, stability of the device is high. Furthermore, Poly-Si has excellent semiconductor characteristics, and has been extensively used in electronic industries. The α-Si process technologies is simple and mature, has a low cost, and is suitable for large size liquid crystal display (LCD) display panel and a cheat electrophoresis display (EPD).

Doping of the first electrode 104e is high concentration doping (P+/N+), and can be low concentration doping (P−/N−), The first electrode 104e is configured to serve as a N-type doped layer or a P-type doped layer in the photosensitive element S. a doping method of the first electrode 104e is adjusted according to requirements of a specific device of the photosensitive element S. When the first electrode 104e is N-type doping, the second electrode 114 can have no doping. When the first electrode 104e is P-type doping, the second electrode 114 is N-type doping. It should be explained that usually a doped pentavalent impurity element forms N-type doping, for example, doped arsenic, boron, nitrogen, or phosphorus, etc., Furthermore, doped trivalent impurity element forms P-type doping, for example, boron, or gallium, etc.

When a material used by the first electrode 104e is metal, and can be manufactured with the gate electrode of the thin film transistor device T in the same layer. At this time, a material used by the first electrode 104e is one of silver (Ag), aluminum (Al), nickel (Ni), chromium (Cr), molybdenum (Mo), copper (Cu), Tungsten (W), or titanium (Ti). Metals such as Silver, aluminum, copper have good conductivity and low costs, and can lower the manufacturing cost while guaranteeing the conductivity.

Optionally, in some embodiments of the present application, with further reference to FIG. 1, a material used by the first electrode 104e and the drain electrode portion 104d is N-type doped polysilicon, and the first electrode 104e and the drain electrode portion 104d are disposed in the same layer. Namely, the drain electrode portion 104d of the thin film transistor device T and the first electrode 104e of the photosensitive element S is a layer of structure. In this embodiment, because a portion of the drain electrode portion 104d of the thin film transistor device T is reused as the first electrode 104e of the photosensitive element S, the photosensitive layer 109 of the photosensitive element S is directly connected to the drain electrode portion 104d through the first electrode 104e, a design of the drain electrode wiring can be omitted to make the structure of the display panel 10 more simple.

Optionally, in some embodiments of the present application, with further reference to FIG. 1, the display panel 10 further comprises a light shielding layer 102, a buffer layer 103, a gate electrode insulation layer 105, a first metal layer 106, a second metal layer 108, a planarization layer 111, a bottom electrode layer 112, a passivation layer 113, and a top electrode layer 114a that are sequentially stacked on one another.

The first metal layer 106 can be configured to form the first metal wiring 106a in the display panel 10 and the gate electrode 106b of the thin film transistor device T, and the second metal layer 108 can be configured to form the second metal wiring 108a in the display panel 10 and the source electrode wiring 108b and the drain electrode wiring of the thin film transistor device T (not shown in FIG. 1). The first metal wiring 106a can be a scan line, the second metal wiring 108a can be a data line. It can be understood that the first metal wiring 106a and the second metal wiring 108a can also be other wirings.

Optionally, the first through hole 107a and the second through hole 107b extend to a surface of a side of the gate electrode insulation layer 105 near the substrate 101. A recess 104e is defined in the source electrode portion 104c. The source electrode wiring 108b extends to the recess 104e and contacts a side of the recess 104e. Namely, the source electrode wiring 108b annularly contacts the source electrode portion 104c. Furthermore, the second metal wiring 108a annularly contacts the first metal wiring 106a. Annular contact increases a contact area between two material layers and mitigates the issue of broken lines between film layers. The recess 104e can penetrate the source electrode portion 104c. Alternatively, a depth of the recess 104e is less than a depth of the source electrode portion 104c.

The thin film transistor device T comprises a light-doping region 104b, a gate electrode 106b, and the source electrode wiring 108b. The gate electrode insulation layer 105 is disposed on the active layer 104. The gate electrode 106b is disposed on the gate electrode insulation layer 105. The interlayer insulation layer 107 is disposed on the gate electrode 106b and extends to the gate electrode insulation layer 105. The first electrode 104e of the photosensitive element S is formed by reusing the drain electrode portion 104d of the thin film transistor device T. The photosensitive layer 109 of the photosensitive element S is disposed on the drain electrode portion 104d. The second electrode 114 of the photosensitive element S is formed by reusing the top electrode layer 114a of the display panel 10.

A protection layer 110 is disposed on a surface of a side of the photosensitive layer 109 of the photosensitive element S away from substrate. The protection layer 110 can be configured to prevent the second metal layer 108 from damaging the photosensitive layer 109 during an etching process.

Optionally, with reference to FIG. 2, FIG. 2 is a partial schematic structural view of an array substrate provided by the embodiment of the present application. A first via hole110a is defined in the protection layer 110. A second via hole110b is defined in the planarization layer 111. A diameter of the first via hole110a is less than a diameter of the second via hole110b.

The bottom electrode layer 112 can serve as a common electrode of the display panel 10, the top electrode layer 114a can serve as a pixel electrode of the display panel 10. Of course, the present application has no limit to functions of the bottom electrode layer 112 and the top electrode layer 114a. Alternatively, the bottom electrode layer 112 can also serve as the pixel electrode of the display panel 10, the top electrode layer 114a can serve as the common electrode of the display panel.

Optionally, the photosensitive element S further comprises the second electrode 114. The second electrode 114 and the top electrode layer 114a are disposed in the same layer. The second electrode 114 is connected to the photosensitive layer 109 through the first via hole110a and the second via hole110b. In some embodiments of the present application, a portion of the top electrode layer 114a is reused as the second electrode 114 of the photosensitive element S. A material used by the top electrode layer 114a is usually metal oxide. In particular, the material of the metal oxide can be one of zinc oxide, indium oxide, indium gallium zinc oxide, indium zinc tin oxide, indium gallium zinc tin oxide, indium tin oxide, indium zinc oxide, indium aluminum zinc oxide, indium gallium tin oxide, or antimony tin oxide. The above materials include excellent conductivity and transparency, and less thicknesses, and would not affect the entire thickness of the display panel. In the meantime, it also can reduce electronic radiation, ultra-violet and infrared harmful to human bodies. In the above materials, materials with high word functions can be selected to manufacture the second electrode 114.

In the display panel 10 provided by the embodiment of the present application, the top electrode layer 114a is reused as an electrode of the photosensitive element S, then the second electrode 114 absorbs no light in a wave range of visible light, more light is allowed to reach the photosensitive layer 109, which improves absorption of the incident interface of the photosensitive layer 109 to light. Therefore, an electrical field generated in the photosensitive element S is stronger and can effectively separate photogenerated electrons and holes, which enhances sensitivity of the photosensitive element S.

With reference to FIG. 3, FIG. 3 is a second schematic structural view of the display panel provided by the embodiment of the present application. A difference from the display panel 10 of the former embodiment is that the thin film transistor device T further comprises a drain electrode wiring 108c. The first electrode 104e comprises a first sub-electrode 1041e and a second sub-electrode 1042e. The gate electrode 106b is disposed on the substrate 101, and the gate electrode 106b and the active layer 104 are insulatively disposed in different layers. The source electrode wiring 108b is connected to the source electrode portion 104c. The drain electrode wiring 108c is connected to the drain electrode portion 104d. The first sub-electrode 1041e and the gate electrode 106b are disposed in the same layer, and are connected to the drain electrode portion 104d through the drain electrode wiring 108c. The second sub-electrode 1042e is disposed on a surface of a side of the first sub-electrode 1041e away from the substrate 101. Optionally, the drain electrode wiring 108c and the source electrode wiring 108b are disposed in the same layer.

Optionally, the display panel 10 further comprises the gate electrode insulation layer 105 and the interlayer insulation layer 107. The thin film transistor device T further comprises the gate electrode 106b, the source electrode wiring 108b and the drain electrode wiring 108c. The gate electrode insulation layer 105 is disposed on the active layer 104. The gate electrode 106b is disposed on the gate electrode insulation layer 105. The interlayer insulation layer 107 is disposed on the gate electrode 106b and extends to the gate electrode insulation layer 105. The first through hole 107a, the second through hole 107b, and a third through hole 107c are defined in the interlayer insulation layer 107. The source electrode wiring 108b and the drain electrode wiring 108c are connected to the source electrode portion 104c and the drain electrode portion 104d respectively through the first through hole 107a. The second sub-electrode 1042e is connected to the first sub-electrode 1041e through the second through hole 107b. The drain electrode wiring 108c is further connected to the first sub-electrode 1041e through the third through hole 107c.

Optionally, the second through hole 107b extends from a surface of a side of the interlayer insulation layer away from the substrate 101 to a surface of a side of the first sub-electrode 1041e away from the substrate 101.

In an embodiment of the present application, the first electrode 104e of the photosensitive element S has the first sub-electrode 1041e and the second sub-electrode 1042e. When the first metal layer 106 of the thin film transistor device T is disposed, the first sub-electrode 1041e of the photosensitive element S is patterned and formed simultaneously. Using metal as the first electrode of the photosensitive element S can conduct out a photogenerated current and simultaneously perform a light shielding function to prevent backlight interference. The second sub-electrode 1042e can be formed by phosphorus doped amorphous silicon to perform a bridge function to the photosensitive layer 109 and the metallic first sub-electrode 1041.

Optionally, a side of the photosensitive layer 109 away from the substrate 101 provided by the embodiment of the present application protrudes from a surface of a side of the interlayer insulation layer 107 away from the substrate 101, and a width of a side of the photosensitive layer 109 away from the substrate 101 is greater than a width of a side of the second through hole 107b away from the substrate 101.

In the embodiment of the present application, the photosensitive element S is equal to a diode. Under a reverse bias state, i.e. under a condition of the photosensitive element S without light irradiation, reverse bias current is low, and then the photosensitive element S does not switch on and generates no current. When external ambient light irradiates the photosensitive element S, the photosensitive element S absorbs ambient light. Ambient light makes the photosensitive element S generate pairs of electrons and holes. In the meantime, under an effect of a built-in electrical field of the photosensitive element S, pairs of photogenerated electrons and holes are separated to generate photogenerated current. The thin film transistor device T connected to the photosensitive element S is controlled, a variation of the photogenerated current is sensed at a detection end to further recognize and reflect intensity of ambient light.

Accordingly, the embodiment of the present application further provides a display panel manufacturing method. With reference to FIG. 4, FIG. 4 is a flowchart of a display panel manufacturing method provided by the embodiment of the present application. Specifically, the display panel manufacturing method provided by the present application specifically comprises steps as follows:

A step 10 comprises providing a substrate.

A step 11 comprises forming a thin film transistor device and a photosensitive element on the substrate.

The step of forming a thin film transistor device and a photosensitive element on the substrate comprises as follows:

A step 111 comprises forming an active layer on the substrate; and.

A step 112 comprises doping two ends of the active layer to form a semiconductor portion and a source electrode portion and a drain electrode portion located on two sides of the semiconductor portion.

Optionally, an active film layer is formed by amorphous silicon, the amorphous silicon is converted to polysilicon by excimer laser annealing. Ions are implanted into two ends of an outer of the polysilicon layer by a ions injection machine. An annealing activation step is further performed to sequentially arrange disordered ions on locations of silicon atoms to make a portion implanted with particles easily generate Ohmic contact to form a source electrode portion and a drain electrode portion. Optionally, lightly doping can be further performed between the source electrode portion, the drain electrode portion, and the semiconductor portion to form a light-doping region.

A step 113 comprises forming an interlayer insulation layer on the substrate.

A step 114 comprises forming a first through hole and a second through hole in the interlayer insulation layer by a same photomask.

A step 115 comprises forming a source electrode wiring on the substrate, wherein the source electrode wiring is connected to the source electrode portion through the first through hole.

A step 116 comprises forming at least a portion of the photosensitive element in the second through hole.

Contact holes of the photosensitive layer of the photosensitive element and the first electrode and contact holes of the source electrode wiring, the drain electrode wiring, the source electrode portion, and the drain electrode portion can be manufactured by the same process, which achieves omitting photomasks to lower the cost.

Optionally, the step of forming a photosensitive element on the substrate comprises steps as follows:

A step 11a comprises forming a first electrode on the substrate, wherein the first electrode is electrically connected to the drain electrode portion.

It should be explained that the first electrode of the photosensitive element provided by the embodiment of the present application can be formed by reusing the drain electrode portion of the thin film transistor device. first electrode can also be formed from the same metal layer of the gate electrode, and form as the second sub-electrode commonly with the doped amorphous silicon. Therefore, the first electrode is formed by reusing the drain electrode portion, disposing the first electrode on the substrate is doping two sides of the active layer and then forming the drain electrode portion. When the first electrode is the gate electrode of the same metal layer and is formed with the doped amorphous silicon, it is required to dispose the first electrode after the doping step of the active layer.

A step 11b comprises forming a photosensitive layer on the interlayer insulation layer, wherein the photosensitive layer is connected to the first electrode through the second through hole.

Optionally, the photosensitive layer can be deposited by a deposition method. A light absorbing material is disposed on a side of the first electrode away from substrate first, then a film layer of the light absorbing material is patterned by an exposing and etching process to obtain a photosensitive layer.

Optionally, the step of forming photosensitive layer a on the interlayer insulation layer comprises steps as follows:

A step 1151 comprises depositing a photosensitive material on the substrate.

A step 1152 comprises patterning the photosensitive material to from a photosensitive layer, and simultaneously making the first through hole extend to a surface of a side of the active layer near the substrate.

Specifically, the photosensitive material can be patterned by an exposing and etching process. During patterning the photosensitive material, the first through hole is also etched such that the first through hole extends to a surface of a side of the active layer near the substrate. As such, source electrode wiring can annularly contact the active layer, which can increase a contact area between the source electrode wiring and the source electrode portion and effectively lower a resistance.

Optionally, first electrode comprises a first sub-electrode and a second sub-electrode, after the step of forming an active layer on the substrate, the method further comprises steps as follows:

A step 131 comprises forming a gate electrode insulation layer on the active layer.

A step 132 comprises forming a gate electrode and the first sub-electrode on the gate electrode insulation layer.

A step 133 comprises forming an interlayer insulation layer on the gate electrode.

A step 134 comprises forming a third through hole in the interlayer insulation layer by the same photomask forming the first through hole and the second through hole.

A step 135 comprises forming a drain electrode wiring and the second sub-electrode on the interlayer insulation layer, wherein the source electrode wiring and the drain electrode wiring are connected to the source electrode portion and the drain electrode portion respectively through the first through hole, the second sub-electrode is connected to the first sub-electrode through the second through hole, and the drain electrode wiring is connected to the first sub-electrode through the third through hole.

Contact holes of the second sub-electrode and the first sub-electrode of the photosensitive element, the contact holes of the source electrode wiring, the drain electrode wiring, the source electrode portion, and the drain electrode portion, and the contact holes of the drain electrode wiring and the first sub-electrode, can be formed by the same process, which achieves omitting photomask to further lower the cost.

In some embodiments, With reference to FIGS. 5a to 5j, FIGS. 5a to 5j are schematic views of steps of the display panel manufacturing method provided by the embodiment of the present application.

With reference to FIG. 5a, the light shielding layer 102 is manufactured on the substrate 101 and is patterned by an exposing and etching process. The light shielding layer 102 is configured to shield a bottom portion of the thin film transistor device and the photosensitive element to exclude signal interference of ambient light and other light source, can drastically lower the interference of the ambient light and other light source to the photosensitive element and effectively increases a signal nose ratio of the display panel.

Further, with reference to FIGS. 5b and 5c, a buffer layer 103 and a layer of amorphous silicon are manufactured. Then, by a quasi-molecular laser annealing process, the amorphous silicon layer is converted to polysilicon layer to form the active layer 104. Phosphorus ions is doped to form an N+ source and drain region, i.e., the semiconductor portion 104a, the source electrode portion 104c, and the drain electrode portion 104d as shown in FIG. 5c.

With reference to FIG. 5d, the gate electrode insulation layer 105 and the first metal layer 106 are deposited. The first metal layer GE is patterned to form a first metal wiring 106a and a gate electrode 106b. The gate electrode 106b can serve as a top gate of a display thin film transistor in the display region. N-ions implanting is performed by shielding of the gate electrode 106b to form the light-doping region 104b.

Then, with reference to FIG. 5e, the interlayer insulation layer 107 is deposited, the first through hole 107a and the second through hole 107b are defined in the interlayer insulation layer 107 by exposing and etching. The first through hole 107a is configured to connect the source electrode wiring to the source electrode portion 104c. The second through hole 107b is configured to connect the photosensitive layer to the first electrode.

With reference to FIG. 5f, the photosensitive layer 109 is deposited. A layer of the protection layer 110 is manufactured on the photosensitive layer 109 to protect the photosensitive layer 109. The photosensitive layer 109 and the protection layer 110 are exposed and etched simultaneously to prevent later processes patterning and etching the source electrode wiring and the drain electrode wiring of the of the thin film transistor device from damaging the photosensitive layer 109. When the photosensitive layer 109 and the protection layer 110 are exposed and etched, the first through hole 107a and the second through hole 107b are further etched.

Further, with reference to FIG. 5g, the second metal layer 108 is manufactured, and the second metal layer 108 is patterned to form the second metal wiring 108a and the source electrode wiring 108b. Because the first through hole 107a and the second through hole 107b are etched in the former step, contact between the second metal wiring 108a and the first metal wiring 106a, and contact between the source electrode wiring 108b and the source electrode portion 104c are annular contact. Annular contact increases a contact area between two material layers and mitigates the issue of broken lines between film layers.

With reference to FIGS. 5h and 5i, a planarization layer 111 is deposited. The planarization layer 111 can adopt an organic material, and can also adopt an insulation layer material such as silicon nitride or silicon oxide. Then, the bottom electrode layer 112 is deposited on the planarization layer 111. The bottom electrode layer 112 serves as a common electrode of the display panel.

Then, with reference to FIG. 5j, the passivation layer 113 is deposited. A first aperture 113a and a second aperture 113b are defined in the passivation layer by exposing and etching. Finally, a top electrode layer is deposited and is patterned by exposing and etching to form a pixel electrode 114a, which obtains the display panel 10 as shown in FIG. 1. The pixel electrode 114 can be reused as the second electrode 114 of the photosensitive element S.

The display panel manufacturing method provided by the embodiment of the present application manufactures a display panel 10. The display panel 10 integrates the amorphous silicon type photosensitive element S with excellent performance into the display panel to achieve an ambient light sensing function and simplify processes. The photosensitive layer 109 in the photosensitive element S and the second through hole 107b contacting the lower first electrode 104e, are formed by the same photomask with the source electrode wiring 108b in the thin film transistor device T and the first through hole 107a of the lower source electrode portion 104c, which effectively simplifies process.

The display panel and the display panel manufacturing method provided by the embodiment of the present application are described in detail as above. In the specification, the specific examples are used to explain the principle and embodiment of the present application. The above description of the embodiments is only used to help understand the method of the present application and its spiritual idea. Meanwhile, for those skilled in the art, according to the present the idea of invention, changes will be made in specific embodiment and application. In summary, the contents of this specification should not be construed as limiting the present application.

1. A display panel, comprising:
a substrate;
a thin film transistor device, wherein the thin film transistor device is disposed on the substrate, the thin film transistor device comprises an active layer, an interlayer insulation layer, and a source electrode wiring, the active layer comprises a semiconductor portion and a source electrode portion and a drain electrode portion on two sides of the semiconductor portion, the interlayer insulation layer is disposed on the active layer, and the source electrode wiring is disposed on the interlayer insulation layer; and
a photosensitive element, wherein the photosensitive element and the thin film transistor device are disposed on a same side of the substrate;
wherein a first through hole and a second through hole are defined in the interlayer insulation layer, the source electrode wiring is connected to the source electrode portion through the first through hole, and at least a portion of the photosensitive element is disposed in the second through hole.

2. The display panel according to claim 1, wherein the photosensitive element at least comprises a first electrode and a photosensitive layer sequentially stacked on each other; wherein the first electrode is electrically connected to the drain electrode portion, and at least a portion of the photosensitive layer is filled in the second through hole.

3. The display panel according to claim 2, wherein a material of the first electrode is one of doped polysilicon, doped amorphous silicon, metal, or a combination thereof, and a material of the photosensitive layer is intrinsic amorphous silicon.

4. The display panel according to claim 2, wherein a material of the first electrode and the drain electrode portion are is N-type doped polysilicon, and the first electrode and the drain electrode portion are disposed in a same layer.

5. The display panel according to claim 4, wherein the second through hole extends from a surface of a side of the interlayer insulation layer away from the substrate to a surface of a side of the first electrode away from the substrate.

6. The display panel according to claim 4, wherein the display panel further comprises gate electrode insulation layer, the thin film transistor device further comprises gate electrode, the gate electrode insulation layer is disposed on the active layer, the gate electrode is disposed on the gate electrode insulation layer, the interlayer insulation layer is disposed on the gate electrode and extends to the gate electrode insulation layer, and the first through hole and the second through hole extend to a surface of a side of the gate electrode insulation layer near the substrate.

7. The display panel according to claim 6, wherein a recess is defined in the source electrode portion, the source electrode wiring extends to the recess and contacts the recess.

8. The display panel according to claim 2, wherein the thin film transistor device further comprises gate electrode and drain electrode wiring, the first electrode comprises a first sub-electrode and a second sub-electrode, the gate electrode is disposed on the substrate, and the gate electrode and the active layer are disposed insulatively in different layers, the drain electrode wiring is connected to the drain electrode portion, the drain electrode wiring and the source electrode wiring are disposed in a same layer, the first sub-electrode and the gate electrode are disposed in a same layer, and the first sub-electrode is connected to the drain electrode portion through the drain electrode wiring, and the second sub-electrode is disposed on a surface of a side of the first sub-electrode away from the substrate.

9. The display panel according to claim 8, wherein the display panel further comprises gate electrode insulation layer, the interlayer insulation layer further comprises third through hole, the gate electrode insulation layer is disposed on the active layer, the gate electrode is disposed on the gate electrode insulation layer, the interlayer insulation layer is disposed on the gate electrode and extends to the gate electrode insulation layer, the source electrode wiring and the drain electrode wiring are connected to the source electrode portion and the drain electrode portion respectively through the first through hole, the second sub-electrode is connected to the first sub-electrode through the second through hole, the drain electrode wiring is further connected to the first sub-electrode through the third through hole.

10. The display panel according to claim 9, wherein the second through hole extends from a surface of a side of the interlayer insulation layer away from the substrate to a surface of a side of the first sub-electrode away from the substrate.

11. The display panel according to claim 2, wherein the display panel further comprises a protection layer, the protection layer is disposed on a surface of a side of the photosensitive layer away from the substrate.

12. The display panel according to claim 11, wherein the display panel further comprises top electrode layer, the top electrode layer is disposed on the protection layer, the photosensitive element further comprises a second electrode, the second electrode and the top electrode layer are disposed in a same layer, a first via hole is defined in the protection layer, the second electrode is connected to the photosensitive layer through the first via hole.

13. The display panel according to claim 12, wherein the display panel further comprises a planarization layer, the planarization layer is disposed on the protection layer; wherein a second via hole is defined in the planarization layer, a diameter of the first via hole is less than a diameter of the second via hole, the top electrode layer and the second electrode are disposed on the planarization layer, and the second electrode is connected to the photosensitive layer through the first via hole and the second via hole.

14. The display panel according to claim 2, wherein a side of the photosensitive layer away from the substrate protrudes from a surface of a side of the interlayer insulation layer away from the substrate, and a width of a side of the photosensitive layer away from the substrate is greater than a width of a side of the second through hole away from the substrate.

15. The display panel according to claim 1, wherein the display panel further comprises a light shielding layer, a buffer layer, a gate electrode insulation layer, a first metal layer, a second metal layer, a planarization layer, a bottom electrode layer, a passivation layer, and a top electrode layer sequentially stacked on one another.

16. The display panel according to claim 15, wherein the photosensitive element comprises a first electrode, a photosensitive layer, and a second electrode sequentially stacked on one another; the first electrode is formed by the drain electrode portion that is reused, the photosensitive layer is disposed on the drain electrode portion, the second electrode is formed by the top electrode layer in the display panel that is reused.

17. A display panel manufacturing method, comprising:
providing a substrate;
forming a thin film transistor device and a photosensitive element on the substrate;
wherein the step of forming a thin film transistor device and a photosensitive element on the substrate comprises:
forming an active layer on the substrate;
doping two ends of the active layer to form a semiconductor portion and a source electrode portion and a drain electrode portion on two sides of the semiconductor portion;
forming an interlayer insulation layer on the substrate;
forming a first through hole and a second through hole in the interlayer insulation layer by a same photomask;
forming a source electrode wiring on the substrate, wherein the source electrode wiring is connected to the source electrode portion through the first through hole; and
forming at least a portion of the photosensitive element in the second through hole.

18. The display panel manufacturing method according to claim 17, wherein the step of forming a photosensitive element on the substrate, comprises steps as follows:
forming a first electrode on the substrate, wherein the first electrode is electrically connected to the drain electrode portion; and
forming a photosensitive layer on the interlayer insulation layer, wherein the photosensitive layer is connected to the first electrode through the second through hole.

19. The display panel manufacturing method according to claim 18, wherein the step of forming a photosensitive layer on the interlayer insulation layer, comprises steps as follows:
depositing a photosensitive material on the substrate; and
patterning the photosensitive material to from a photosensitive layer, and simultaneously making the first through hole extend to a surface of a side of the active layer near the substrate.

20. The display panel manufacturing method according to claim 18, wherein the first electrode comprises a first sub-electrode and a second sub-electrode, after the step of forming an active layer on the substrate, the method further comprises steps as follows:
forming a gate electrode insulation layer on the active layer; and
forming a gate electrode and the first sub-electrode on the gate electrode insulation layer;
forming an interlayer insulation layer on the gate electrode;
forming a third through hole in the interlayer insulation layer by the same photomask forming the first through hole and the second through hole; and
further forming a drain electrode wiring and the second sub-electrode on the interlayer insulation layer, wherein the source electrode wiring and the drain electrode wiring are connected to the source electrode portion and the drain electrode portion respectively through the first through hole, the second sub-electrode is connected to the first sub-electrode through the second through hole, and the drain electrode wiring is connected to the first sub-electrode through the third through hole.
